(19) United States
(12) Patent Application Publication
(10) Pub. No.: US 2007/0170462 A1
(43) Pub. Date: Jul. 26, 2007

(54) Photo sensor and preparation method thereof

(75) Inventors: Yung-Jane Hsu, Hsinchu (TW); Kuang-Sheng Lai, Hsinchu (TW)

Correspondence Address: BACON & THOMAS, PLLC, 625 SLATERS LANE, FOURTH FLOOR, ALEXANDRIA, VA, 22314, US

(73) Assignee: Fronted Analog and Digital Technology Corporation, Taipei (TW)

(21) Appl. No.: 11/339,543

(22) Filed: Jan. 26, 2006

(51) Int. Cl. H01L 31/109

(52) U.S. Cl. 257/187; 257/462; 438/309; 257/E31.053

(57) ABSTRACT

A novel structure of photo sensor is disclosed. The equivalent circuit of the invented photo sensor comprises a photo transistor integrated with a surface photo sensor. The structure of the surface photo sensor is substantially identical to the base-emitter junction of the photo transistor and may be prepared in the same process. The junction depletion region of the surface photo sensor locates adjacent to the light incident surface, whereby decay of incident light is minimal and more electron-hole pairs are generated. The present invention also discloses semiconductor material containing the invented photo sensor assembly of the invented photo sensor and method for preparation of the photo sensor, the semiconductor material and their assemblies.

### FIELD OF THE INVENTION

The present invention relates to a novel photo sensor and its preparation method, especially to a novel structure of photo sensor and its preparation method. The present invention discloses semiconductor material for the invented photo sensor and its assembly, and assembly comprising the invented photo sensor, and method for preparation thereof. The present invention discloses a mechanism for photo sensor that provides additional photo sensing region adjacent to surface of photo transistor in order to enhance the sensitivity of photo sensor, as well as process for preparation of the mechanism.

### BACKGROUND OF THE INVENTION

In the conventional photo transistor, taking the NPN type photo transistor as an example, the major photo sensing region locates at the base-collector junction. When the depletion region at the base-collector junction receives incident light, electron-hole pairs are generated. Holes with positive charge are swapped from the depletion region by the built-in electrical field and enter the base region, forming photo current. Such photo current excites greater emitter current and forward biases the base-emitter junction, thus generates a collector terminal current that has a gain.

FIG. 1 depicts the structure of a conventional photo transistor. As shown in this figure, a conventional photo transistor has a substrate 10 and an N-P-N layer structure formed on the substrate, wherein each layer has different kind and concentration of dopants. The N-P-N layer structure includes an N layer 11 at bottom, a P layer 12 in middle and an N layer 13 at top. At the border of the P layer 12 and the N layers 11, 13 are junctions. Electrodes are prepared at the N layer 11, the P layer 12 and the N layer 13. A photo transistor is thus prepared. The final structure of such a conventional photo transistor is shown in FIG. 2.

In the photo transistor as shown in FIG. 2, the upper N layer 11 functions as light receiving surface. The electrode 21 connected to this N layer is the emitter of the photo transistor. Electrode 23 of the N layer 13 at the opposite side functions as collector. Electrode 22 of the P layer 12 is its base. Junction 12a between the base layer 12 and the collector layer 13 functions as photo detecting junction. The operation of the photo transistor was as described above. If the photo transistor is a P-N-P type, it would have similar structure and operation as the N-P-N type.

When light beams project to a semiconductor layer, power of the light would exponentially decay along its penetration depth. As a result, light with the strongest power may be detected at the surface region of the semiconductor layer. If the photo detection region 12a of the photo transistor is positioned at this surface region, better detection efficiency may be obtained. However, the photo detection region of the conventional photo transistor is the depletion region of its base-collector junction, which is not positioned at or close to the surface of the semiconductor layer. Improvements in the photo detection efficiency are needed.

To estimate range of wavelength of detectable light of a semiconductor material, the following formula may be used:

$$λ = \frac{1.24}{E g} ,$$

wherein λ is wavelength of detectable light (μm); Eg represents energy band-gap of the semiconductor material (eV).

From the above equation it may be known that, since the energy band-gap of single-crystalline silicon is about 1.12 eV, wavelength of light detectable by conventional pure silicon-based photo transistor is approximately smaller than 1,100 nm. In order to detect grater wavelengths such as 1,310 nm or 1,550 nm, as used in the optical fiber communication system, III-V semiconductor components are used. However, the III-V materials are expensive and their preparation process is not compatible with the most popular silicon base CMOS processes. It is thus necessary to provide a novel photo sensor that is able to detect wavelengths in a range covering what are used in the optical fiber communication systems. It is also necessary to provide a novel photo sensor whose preparation process may be compatible with the most popular silicon base CMOS processes.

### OBJECTIVES OF THE INVENTION

The objective of this invention is to provide a novel photo sensor, wherein photo detective region is provided at adjacent to its surface, so to improve the detection efficiency of photo sensors.

Another objective of this invention is to provide a photo sensor with effectively extended range of detectable wavelengths.

Another objective of this invention is to provide a photo sensor whose preparation process may be compatible with popular silicon-based semiconductor processes.

Another objective of this invention is to provide a photo sensor with an enlarged base-emitter junction whereby its light detective region is enlarged.

Another objective of this invention is to provide a photo sensor with modified base-emitter junction, whereby range of detectible wavelength is extended.

Another objective of this invention is to provide a novel process for preparation of photo sensor that is compatible with popular silicon-based semiconductor processes.

Another objective of this invention is to provide a method for preparation of photo sensor that is compatible with the standard Silicon-Germanium BiCMOS process.

### SUMMARY OF THE INVENTION

According to this invention, a novel photo sensor is disclosed. The invented photo sensor comprises: a first polar semiconductor layer; a second polar semiconductor layer exhibiting a polarity opposite to that of said first polar semiconductor layer, surrounded by said first polar semiconductor layer and having a junction with said first polar semiconductor layer and a region exposed to incident light; a third polar semiconductor layer exhibiting a polarity opposite to that of said second polar semiconductor layer, surrounded by said second polar semiconductor layer and having a junction with said second polar semiconductor layer and a region exposed to said incident light; a fourth polar semiconductor layer exhibiting a polarity opposite to that of said second polar semiconductor layer, surrounded by said second polar semiconductor layer and having a junction with said second polar semiconductor layer and a region exposed to said incident light; and necessary electrodes to pick up photo detection signals from said photo sensor; wherein said third polar semiconductor layer and said fourth polar semiconductor layer are isolated.

The equivalent circuit of the invented photo sensor may be understood as a conventional photo transistor integrated with a surface photo sensor. The structure of the surface photo sensor is in substance identical with the emitter-base structure of the photo transistor and may be prepared in the preparation of the photo transistor. The depletion region at junction of the surface photo sensor is positioned at adjacent to the light incident surface of the element, so to detect incident light at its surface regions and to generate electron-hole pairs in a larger quantity. When an N-P-N type photo transistor is included in the photo sensor of this invention, holes generated by incident light may enter the base of the photo transistor directly. As a result, greater output current may be obtained at the collector of the photo transistor. This invention also discloses semiconductor material comprising the invented photo sensor, assembly comprising the invented photo sensor and methods for preparation of said photo sensor, said semiconductor material and said photo sensor assembly.

These and other objectives and advantages of this invention may be clearly understood from the detailed description by referring to the following drawings.

### BRIEF DESCRIPTION OF THE DRAWINGS

FIG. 1 depicts the structure of a conventional photo transistor.

FIG. 2 shows the structure of a conventional photo transistor with electrodes.

FIG. 3 depicts the structure of semiconductor material in the preparation of the photo sensor of this invention.

FIG. 4 is the structure of the photo sensor of this invention with electrodes.

FIG. 5 shows the flowchart of method for preparation of the photo sensor semiconductor material of FIG. 3.

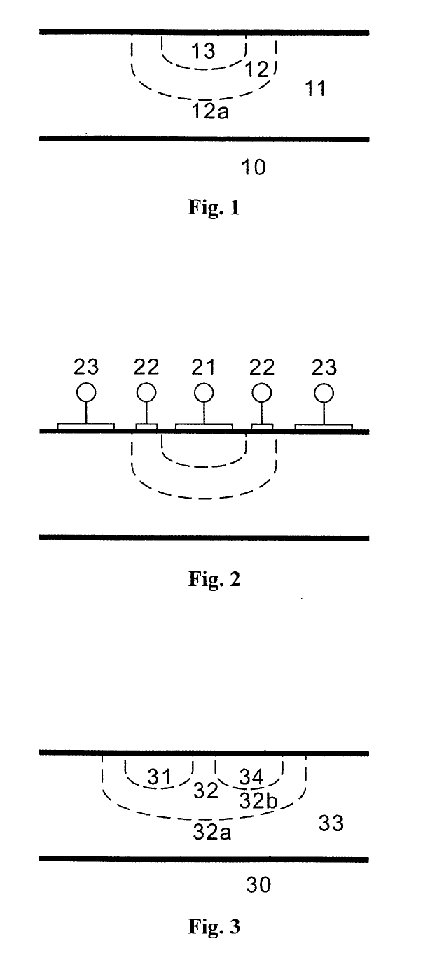

### DETAILED DESCRIPTION OF THE INVENTION

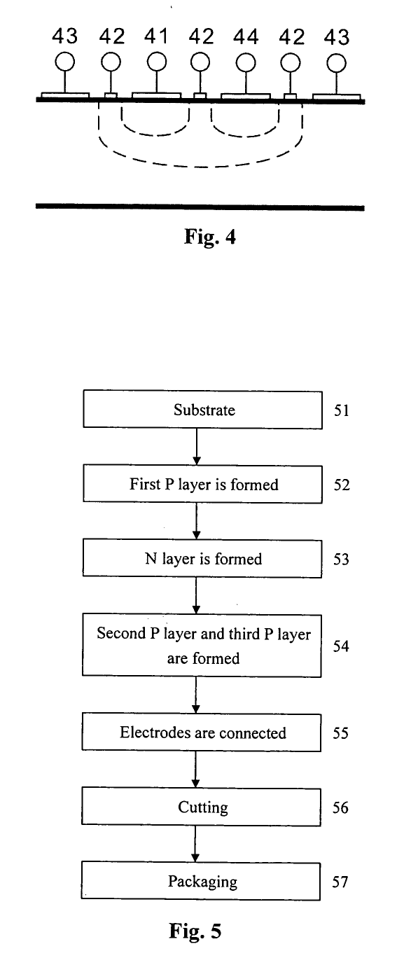

The followings are detailed description of the photo sensor of the present invention, when implemented under the basic structure of a P-N-P type photo transistor. FIG. 3 depicts the structure of semiconductor material in the preparation of the photo sensor of this invention. As shown in this figure, the semiconductor material comprises a substrate 30; a first P layer 33 prepared in or on top of the substrate 30; an N layer prepared above said first P layer 33 and within the area defined by said first P layer 33; a second P layer 31 prepared above said N layer 32 and within the area defined by said N layer 32; and a third P layer 34 prepared above said N layer 32 and within the area defined by said N layer 32 but isolated with said second P layer 31. In addition, the semiconductor material further comprises collector electrode 43 connected to said first P layer 33, base electrode 42 connected to said N layer 32, emitter electrode 41 connected to said second P layer 31 and surface photo sensor electrode 44 connected to said third P layer 34. FIG. 4 is the final structure of the photo sensor of this invention. In this figure, 41 represents emitter of the invented photo sensor, 42 represents its base, 43 represents its collector and 44 represents the surface photo sensor electrode.

As known by those skilled in the art, in the semiconductor material as shown in FIG. 3, if the P layers are replaced by N layers and the N layer is replace by a P layer, a circuit similar to that of FIG. 4 may be formed. In other words, in the following detailed description, the structure as shown in FIG. 3 will be used as an example of this invention. The present, however, shall not be limited to the structure of FIG. 3. For example, when the polarities shown in FIG. 3 are reversed, a photo sensor exhibiting similar functions may also be prepared.

Now refer to FIG. 5. FIG. 5 shows the flowchart of method for preparation of the photo sensor semiconductor material of FIG. 3. Method for preparation of the semiconductor material of FIG. 3 will be described below.

In the preparation of the semiconductor material of FIG. 3, at first at 51 a semiconductor substrate 30 is obtained. Material for the substrate 30 may be silicon-based materials, such as materials containing silicon or its compositions, including SiGe, SiC etc., or other compound semiconductors including semiconductor materials prepared from III-V elements or II-VI elements. Then at 52 impurities are doped into selected areas of the substrate 30, to form first P layer 33 in said areas. Any doping technology may be applied in this step. Applicable doping technologies include thermal diffusion and ion implantation. It is also possible to prepare a P type electrode layer as the substrate by doping the substrate when it is prepared. Dopants that may be added include Group III elements and other suited materials. As described above, in this embodiment a P-N-P type photo transistor will be prepared. If an N-P-N type photo transistor will be prepared, in this step the substrate shall be doped to form an N layer. As a result, dopants may be Group V elements and other materials suited in forming an N layer. As to concentration of dopants, reaction temperature, pressure and time, they may be determined according to practical needs. No particular requirements or limitations in these conditions, as long as the P layer 33 so prepared may exhibit standard features of the positive polarity. The P layer 33 so prepared will function as collector 43 of the photo sensor.

Thereafter, at 53 an N layer 32 is formed in the first P layer 33 at selected areas. In this embodiment, N layer 32 is surrounded by the first P layer 33. The N layer 32 may be formed by doping impurities using any available method, including thermal diffusion and ion implantation. It is also possible to form the N layer 32 above selected areas within the area defined by the first P layer 33. When forming the N layer 32, any applicable method may be used. For example, it is possible to deposit a material layer on the first P layer 33 and then dope in the added material layer to perform the negative polarity. It is also possible to dope the added material layer during its preparation, so to form the N layer 32 directly. Here, any available method in forming and doping the material layer may be applied. The process in this step is similar to that of step 52. Detailed description is thus omitted. The N layer 32 so obtained will function as base 42 of the photo sensor.

Further, at 54 second P layer 31 and third P layer 34 are formed in selected areas within the area defined by the N layer 32. Method to form the second and third P layers 31, 34 may be similar with that of the previous step, provided that dopants used in this step are different from that of Step 53. In the present invention, second and third P layers 31 and 34 are isolated without contacts between them.

In the above-described process, all reaction conditions may be determined according actual needs. Materials of the substrates of the first P layer, the N layer, and second and the third P layers may be identical or different. Dopants added to first, second and third P layers may be identical or different. However, if substrate materials and dopants for second and third P layers are identical, number of steps in the process and preparation costs may be reduced. This, of course, is not any requirement or limitation. In some preferred embodiments, material of first P layer 33 may be crystalline silicon. Material for N layer 32 may be SiGe. Material for second and third P layers 31, 34 may be poly silicon. The second and third P layers 31, 34 may function as emitter layer and surface photo sensor electrode of the invented photo sensor, respectively, depending on electrodes connected thereto and concentrations of dopants.

At 55, electrodes 43, 42, 41 and 44 are connected to the first P layer 33, the N layer 32 and the second and third P layers 31 and 34 of the photo sensing semiconductor material so prepared. The photo sensor is thus prepared. The electrodes may be connected to the related layers using any applicable method, including screen printing, deposition, spitting, vapor deposition, plating etc. The photo sensor so prepared may contain a plurality of photo sensor units prepared in wafer. Therefore, at 56 the wafer is cut to obtain units of photo sensor and the units are packaged at 57.

In some embodiments of this invention, electrodes are connected to the photo sensing semiconductor material after cutting. In addition, it is possible to form particular wires to connect a plurality of photo sensors before they are cut. Furthermore, in some other embodiments, the substrates are prepared from transparent materials. In some further embodiments a reflection layer (not shown) is provided at the lower surface (non-incident side) of the substrate 30 to further enhance its photo sensing effects. It is also preferable to prepare the electrodes using transparent materials such as ITO and TO.

The photo sensor so prepared has two depletion regions to detect incident lights and to convert such lights into current outputs. If compared with the conventional photo transistor, the invented photo sensor provides an additional junction 32b between its N layer 32 and third P layer 34, in addition to the junction 32a between its base and collector. As a result, no matter the incident light is visible light with short wavelengths (such as 400-700 nm) or long wavelength light (such as light waves with the wavelength of 1,310 nm as used in the optical fiber communication system), they may effectively detected by the invented photo sensor.

Nevertheless, the equivalent circuit of the invented photo sensor includes a photo transistor (including first P layer, N layer and second P layer in the above example) and a surface photo sensor (including third P layer and N layer). In them, one terminal of the surface photo sensor happens to be base of the photo transistor. When the incident light reaches the surface photo sensor, carriers (electrons) so generated will enter the base directly, so that amplified currents are output from collector of the photo transistor. The photo reaction efficiency of this invention is thus far higher than that of the conventional photo transistors.

The photo sensor of this invention may be prepared by using the standard SiGe BiCMOS process. No special process modification is needed. In the process, the structure of the surface photo sensor and the emitter-base structure of the photo transistor are identical and may be prepared simultaneously. The process is thus made simplified. With the invented structure, the junction depletion region of the SiGe surface photo sensor locates at the SiGe region. Since the energy band-gap of the SiGe material is smaller than that of pure silicon, the SiGe surface photo sensor of this invention may be used to detect lights with longer wavelengths. As a result, the detectable range may be extended to include infrared wavelengths, whereby the invented photo sensor may be used in the optical fiber communication system.

In addition, in the circuit of FIG. 4, if base 42 and surface photo sensor electrode 44 are floating, the photo sensor may operate in the photo-voltage mode. On the other hand, if base 42 is floating and surface photo sensor electrode 44 is biased, the photo sensor may operate in the photo-current mode. More applications are thus provided.

In the photo sensor of this invention, the emitter of the photo transistor does not provide any photo detection function. Therefore, it is preferable to reduce the area of the emitter in the light incident surface. On the other hand, the region of the surface photo sensor is preferably expanded to as much as possible in order to further enhance the photo detective effects. In some embodiments of the present invention, the region of the surface photo sensor electrode has a ring shape and surrounds the emitter region. Such design may further increase the photo detective effects of this invention.

As the present invention has been shown and described with reference to preferred embodiments thereof, those skilled in the art will recognize that the above and other changes may be made therein without departing from the spirit and scope of the invention.

What is claimed is:

1. A photo sensing semiconductor material, comprising:
a first polar semiconductor layer;
a second polar semiconductor layer exhibiting a polarity opposite to that of said first polar semiconductor layer, surrounded by said first polar semiconductor layer and having a junction with said first polar semiconductor layer and a region exposed to incident light;
a third polar semiconductor layer exhibiting a polarity opposite to that of said second polar semiconductor layer, surrounded by said second polar semiconductor layer and having a junction with said second polar semiconductor layer and a region exposed to said incident light; and
a fourth polar semiconductor layer exhibiting a polarity opposite to that of said second polar semiconductor layer, surrounded by said second polar semiconductor layer and having a junction with said second polar semiconductor layer and a region exposed to said incident light;
characterized in that said third polar semiconductor layer and said fourth polar semiconductor layer are isolated.

2. The photo sensing semiconductor material according to claim 1, further comprising a substrate positioned at a side of said first polar semiconductor layer opposite to said incident light.

3. The photo sensing semiconductor material according to claim 2, wherein said substrate comprises a transparent layer.

4. The photo sensing semiconductor material according to claim 2, wherein said substrate comprises a non-transparent layer.

5. A photo sensor, comprising:
a first polar semiconductor layer;
a second polar semiconductor layer exhibiting a polarity opposite to that of said first polar semiconductor layer, surrounded by said first polar semiconductor layer and having a junction with said first polar semiconductor layer and a region exposed to incident light;
a third polar semiconductor layer exhibiting a polarity opposite to that of said second polar semiconductor layer, surrounded by said second polar semiconductor layer and having a junction with said second polar semiconductor layer and a region exposed to said incident light;
a fourth polar semiconductor layer exhibiting a polarity opposite to that of said second polar semiconductor layer, surrounded by said second polar semiconductor layer and having a junction with said second polar semiconductor layer and a region exposed to said incident light; and
necessary electrodes to pick up photo detection signals from said photo sensor;
characterized in that said third polar semiconductor layer and said fourth polar semiconductor layer are isolated.

6. The photo sensor according to claim 5, further comprising a substrate positioned at a side of said first polar semiconductor layer opposite to said incident light.

7. The photo sensor according to claim 6, wherein said substrate comprises a transparent layer.

8. The photo sensor according to claim 6, wherein said substrate comprises a non-transparent layer.

9. The photo sensor according to claim 5, wherein said first polar semiconductor layer has one electrode positioned in said region exposed to said incident light; said second polar semiconductor layer has one electrode positioned in said region exposed to said incident light; said third polar semiconductor layer has one electrode positioned in said region exposed to said incident light; and said fourth polar semiconductor layer has one electrode positioned in said region exposed to said incident light

10. A photo sensing semiconductor material assembly, comprising a plurality of photo sensing semiconductor material units; wherein at least one photo sensing semiconductor material unit comprises:
a first polar semiconductor layer;
a second polar semiconductor layer exhibiting a polarity opposite to that of said first polar semiconductor layer, surrounded by said first polar semiconductor layer and having a junction with said first polar semiconductor layer and a region exposed to incident light;
a third polar semiconductor layer exhibiting a polarity opposite to that of said second polar semiconductor layer, surrounded by said second polar semiconductor layer and having a junction with said second polar semiconductor layer and a region exposed to said incident light; and
a fourth polar semiconductor layer exhibiting a polarity opposite to that of said second polar semiconductor layer, surrounded by said second polar semiconductor layer and having a junction with said second polar semiconductor layer and a region exposed to said incident light;
characterized in that said third polar semiconductor layer and said fourth polar semiconductor layer are isolated.

11. The photo sensing semiconductor material assembly according to claim 10, further comprising an isolating layer between at least two photo sensing semiconductor material units to isolate said photo sensing semiconductor material units.

12. The photo sensing semiconductor material assembly according to claim 10, wherein said plurality of photo sensing semiconductor material units form a substantial plan.

13. The photo sensing semiconductor material assembly according to claim 10, 11 or 12, further comprising a substrate positioned at a side of said first polar semiconductor layer opposite to said incident light.

14. The photo sensing semiconductor material assembly according to claim 12, wherein said substrate comprises a transparent layer.

15. The photo sensing semiconductor material assembly according to claim 12 wherein said substrate comprises a non-transparent layer.

16. A photo sensor assembly, comprising a plurality of photo sensor units; wherein at least one of said photo sensors comprises:
a first polar semiconductor layer;
a second polar semiconductor layer exhibiting a polarity opposite to that of said first polar semiconductor layer, surrounded by said first polar semiconductor layer and having a junction with said first polar semiconductor layer and a region exposed to incident light;
a third polar semiconductor layer exhibiting a polarity opposite to that of said second polar semiconductor layer, surrounded by said second polar semiconductor layer and having a junction with said second polar semiconductor layer and a region exposed to said incident light;
a fourth polar semiconductor layer exhibiting a polarity opposite to that of said second polar semiconductor layer, surrounded by said second polar semiconductor layer and having a junction with said second polar semiconductor layer and a region exposed to said incident light; and
necessary electrodes to pick up photo detection signals from said photo sensor;
characterized in that said third polar semiconductor layer and said fourth polar semiconductor layer are isolated.

17. The photo sensor assembly according to claim 16, further comprising an isolating layer between at least two photo sensor units to isolate said photo sensor units.

18. The photo sensor assembly according to claim 16, wherein said plurality of photo sensor units form a substantial plan.

19. The photo sensor assembly according to claim 16, 17 or 18, further comprising a substrate positioned at a side of said first polar semiconductor layer opposite to said incident light.

20. The photo sensor assembly according to claim 19, wherein said substrate comprises a transparent layer.

21. The photo sensor assembly according to claim 19, wherein said substrate comprises a non-transparent layer.

22. The photo sensor assembly according to claim 16, 17 or 18, wherein said first polar semiconductor layer has one electrode positioned in said region exposed to said incident light; said second polar semiconductor layer has one electrode positioned in said region exposed to said incident light; said third polar semiconductor layer has one electrode positioned in said region exposed to said incident light; and said fourth polar semiconductor layer has one electrode positioned in said region exposed to said incident light

23. The photo sensor assembly according to claim 22, wherein said electrode comprises transparent electrode.

24. Method for preparation of photo sensing semiconductor material, comprising the steps of:
forming a first polar semiconductor layer;
forming in area defined by said first polar semiconductor layer a second polar semiconductor layer to exhibit a polarity opposite to that of said first polar semiconductor layer, said second polar semiconductor layer being surrounded by said first polar semiconductor layer and having a junction with said first polar semiconductor layer and a region exposed to incident light; and
forming a third polar semiconductor layer and a fourth polar semiconductor layer in area defined by said second polar semiconductor layer, to exhibit a polarity opposite to that of said second polar semiconductor layer; said third and fourth polar semiconductor layers being respectively surrounded by said second polar semiconductor layer and having a junction with said second polar semiconductor layer and a region exposed to said incident light;
characterized in that said third polar semiconductor layer and said fourth polar semiconductor layer are isolated.

25. The method for preparation of photo sensing semiconductor material according to claim 24, further comprising a step of forming a substrate before forming of said first polar semiconductor layer whereby said substrate is positioned at a side of said first polar semiconductor layer opposite to said incident light.

26. The method for preparation of photo sensing semiconductor material according to claim 25, wherein said substrate comprises a transparent layer.

27. The method for preparation of photo sensing semiconductor material according to claim 25, wherein said substrate comprises a non-transparent layer.

28. Method for preparation of photo sensor, comprising the steps of:
forming a first polar semiconductor layer;
forming in area defined by said first polar semiconductor layer a second polar semiconductor layer to exhibit a polarity opposite to that of said first polar semiconductor layer, said second polar semiconductor layer being surrounded by said first polar semiconductor layer and having a junction with said first polar semiconductor layer and a region exposed to incident light;
forming a third polar semiconductor layer and a fourth polar semiconductor layer in area defined by said second polar semiconductor layer, to exhibit a polarity opposite to that of said second polar semiconductor layer; said third and fourth polar semiconductor layers being respectively surrounded by said second polar semiconductor layer and having a junction with said second polar semiconductor layer and a region exposed to said incident light; and
forming necessary electrodes on said first polar semiconductor layer, said second polar semiconductor layer, said third polar semiconductor layer and said fourth polar semiconductor layer to pick up photo detection signals from said photo sensor;
characterized in that said third polar semiconductor layer and said fourth polar semiconductor layer are isolated.

29. The method for preparation of photo sensor according to claim 28, further comprising
a step of forming a substrate before forming of said first polar semiconductor layer whereby said substrate is positioned at a side of said first polar semiconductor layer opposite to said incident light.

30. The method for preparation of photo sensor according to claim 29, wherein said substrate comprises a transparent layer.

31. The method for preparation of photo sensor according to claim 29, wherein said substrate comprises a non-transparent layer.

32. The method for preparation of photo sensor according to claim 28, wherein said step of forming necessary electrodes comprises forming an electrode on said first polar semiconductor layer in said region exposed to said incident light; forming an electrode on said second polar semiconductor layer in said region exposed to said incident light; forming an electrode on said third polar semiconductor layer in said region exposed to said incident light; and forming an electrode on said fourth polar semiconductor layer in said region exposed to said incident light.

33. The method for preparation of photo sensor according to claim 32, wherein said electrodes comprise transparent electrodes.

34. Method for preparation of photo sensing semiconductor material assembly, comprising the steps of:
forming a first polar semiconductor layer;
forming in a plurality of selected areas in area defined by said first polar semiconductor layer a plurality of second polar semiconductor layers to exhibit a polarity opposite to that of said first polar semiconductor layer, each said second polar semiconductor layer being surrounded by said first polar semiconductor layer and having a junction with said first polar semiconductor layer and a region exposed to incident light; and
forming a plurality of third polar semiconductor layer and a plurality of fourth polar semiconductor layer in selected areas in area defined by each of said second polar semiconductor layer, to exhibit a polarity opposite to that of said second polar semiconductor layer; each said third and fourth polar semiconductor layers being surrounded by said second polar semiconductor layer and having a junction with said second polar semiconductor layer and a region exposed to said incident light;
characterized in that each pair of said third polar semiconductor layer and said fourth polar semiconductor layer are isolated.

35. The method for preparation of photo sensing semiconductor material assembly according to claim 34, further comprising the step of forming an isolating layer between at least two photo sensing semiconductor material units, each comprising one second polar semiconductor layer, to isolate said photo sensing semiconductor material units.

36. The method for preparation of photo sensing semiconductor material assembly according to claim 34, wherein said first polar semiconductor layer forms a substantial plan.

37. The method for preparation of photo sensing semiconductor material assembly according to claim 34, 35 or 36, further comprising the step of forming a substrate before forming of said first polar semiconductor layer, whereby said substrate is positioned at a side of said first polar semiconductor layer opposite to said incident light.

38. The method for preparation of photo sensing semiconductor material assembly according to claim 37, wherein said substrate comprises a transparent layer.

39. The method for preparation of photo sensing semiconductor material assembly according to claim 37 wherein said substrate comprises a non-transparent layer.

40. Method for preparation of photo sensor assembly, comprising the steps of:
forming a first polar semiconductor layer;
forming in a plurality of selected areas in area defined by said first polar semiconductor layer a plurality of second polar semiconductor layers to exhibit a polarity opposite to that of said first polar semiconductor layer, each said second polar semiconductor layer being surrounded by said first polar semiconductor layer and having a junction with said first polar semiconductor layer and a region exposed to incident light;
forming a plurality of third polar semiconductor layer and a plurality of fourth polar semiconductor layer in selected areas in area defined by each of said second polar semiconductor layer, to exhibit a polarity opposite to that of said second polar semiconductor layer; each said third and fourth polar semiconductor layers being surrounded by said second polar semiconductor layer and having a junction with said second polar semiconductor layer and a region exposed to said incident light; and
forming necessary electrodes on said first polar semiconductor layer, said plurality of second polar semiconductor layer, said plurality of third polar semiconductor layer and said plurality of fourth polar semiconductor layer, respectively, to pick up photo detection signals from said photo sensor;
characterized in that said third polar semiconductor layer and said fourth polar semiconductor layer are isolated.

41. The method for preparation of photo sensor assembly according to claim 40, further comprising the step of forming an isolating layer between at least two photo sensing semiconductor material units, each comprising one second polar semiconductor layer, to isolate said photo sensing semiconductor material units.

42. The method for preparation of photo sensor assembly according to claim 40, wherein said first polar semiconductor layer forms a substantial plan.

43. The method for preparation of photo sensor assembly according to claim 40, 41 or 42, further comprising the step of forming a substrate before forming of said first polar semiconductor layer, whereby said substrate is positioned at a side of said first polar semiconductor layer opposite to said incident light.

44. The method for preparation of photo sensor assembly according to claim 43, wherein said substrate comprises a transparent layer.

45. The method for preparation of photo sensor assembly according to claim 43, wherein said substrate comprises a non-transparent layer.

46. The method for preparation of photo sensor assembly according to claim 40, 41 or 42, wherein said step of forming necessary electrodes comprises forming a plurality of electrode on said first polar semiconductor layer in said region exposed to said incident light; forming a plurality of electrode on said plurality of second polar semiconductor layer in said region exposed to said incident light; forming a plurality of electrode on said plurality of third polar semiconductor layer in said region exposed to said incident light; and forming a plurality of electrode on said plurality of fourth polar semiconductor layer in said region exposed to said incident light.

47. The method for preparation of photo sensor assembly according to claim 46, wherein said electrodes comprises transparent electrodes.

48. The photo sensing semiconductor material according to claim 1, wherein said fourth polar semiconductor layer forms a ring shape and surrounds said third polar semiconductor layer.

49. The photo sensor according to claim 5, wherein said fourth polar semiconductor layer forms a ring shape and surrounds said third polar semiconductor layer.

50. The photo sensing semiconductor material assembly according to claim 10, wherein each said fourth polar semiconductor layer forms a ring shape and surrounds a third polar semiconductor layer belonging to the same unit.

51. The photo sensor assembly according to claim 16, wherein each said fourth polar semiconductor layer forms a ring shape and surrounds a third polar semiconductor layer belonging to the same unit.

52. The method for preparation of photo sensing semiconductor material according to claim 24, wherein said fourth polar semiconductor layer forms a ring shape and surrounds said third polar semiconductor layer.

53. The method for preparation of photo sensor according to claim 28, wherein said fourth polar semiconductor layer forms a ring shape and surrounds said third polar semiconductor layer.

54. The method for preparation of photo sensing semiconductor material assembly according to claim 34, wherein each said fourth polar semiconductor layer forms a ring shape and surrounds its adjacent third polar semiconductor layer.

55. The method for preparation of photo sensor assembly according to claim 40, wherein said fourth polar semiconductor layer forms a ring shape and surrounds its adjacent third polar semiconductor layer.
